(19) United States
(12) Patent Application Publication
(10) Pub. No.: US 2008/0087460 A1
(43) Pub. Date: Apr. 17, 2008

(54) Apparatus and method for a printed circuit board that reduces capacitance loading of through-holes

(76) Inventor: Pat Fung, Roseville, CA (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/582,740

(22) Filed: Oct. 17, 2006

(51) Int. Cl. H05K 1/11; H01R 12/04

(52) U.S. Cl. 174/262

(57) ABSTRACT

An apparatus and method for a printed circuit board (PCB) for reducing capacitance loading of through-holes. The PCB includes a first electrically conductive via for connecting to the PCB a pin from a connector through a top layer of the PCB. The PCB comprises multiple layers that are electrically isolated from the first electrically conductive via. In addition, the connector provides an electrical signal through the pin that is electrically conductive. The PCB includes a second electrically conductive via that is proximate to the first electrically conductive via. The second electrically conductive via is electrically coupled to one of the multiple layers of the PCB. A trace electrically couples the first electrically conductive via to the second electrically conductive via on a bottom layer of the PCB. The trace allows the pin to be electrically coupled to one of the multiple layers of the PCB.

### TECHNICAL FIELD

The various embodiments of the present invention relate to backplane interconnect systems. More specifically, various embodiments of the present invention relate to a double barrel via structure in a printed circuit board including a through-hole of a connector pin and an adjacent complimentary signal via front panel that flexibly accommodates variously sized devices in a computer chassis.

### BACKGROUND ART

High speed connector performance in digital systems demand higher speeds and bandwidth. This requires fast and reliable communication links between chips, daughter cards, and printed circuit boards (PCBs). In particular, with increasing backplane speeds approaching and exceeding 3 Gbps, connector performance is limited by the parasitic capacitance of the mounting holes in the PCB.

PRIOR ART FIG. 1 is a cross sectional diagram of a PCB 100. The PCB 100 includes, in part, multiple inner layers of power planes, ground planes, and signal layers. As shown, PCB 100 is represented by at least two inner layers, inner layers 105 and 110. These inner layers 105 and 110 could be power or ground planes, or signal layers, for example.

In addition, the PCB 100 includes a plated through-hole, or via, 140. The plated through-hole 140 includes a contact pad 147 on a top surface 150 of the PCB 100, a contact pad 142 on a bottom surface 155 of the PCB 100, and a conductive hole plating 145 for signal transmission. The conductive hole plating 145 creates a barrel of the through-hole 140. An insulating layer 149 separates the conductive areas of the plated through-hole 140 from the inner layers of the PCB 100.

As shown in PRIOR ART FIG. 1, a signal and connector pin 120 is inserted into the barrel of the plated through-hole 140 so as to make contact with the conductive hole plating 145. The connector pin 120 is connected to a connector 130. Typically, the connector 130 includes multiple connector pins that are inserted into corresponding through-holes for attaching to the PCB 100.

When connecting the signal and connector pin 120 to an inner layer of the multi-layer PCB 100 using the plated through-hole 140, a stub is created in the plated through-hole 140 in which the signal current does not traverse. For instance, in PRIOR ART FIG. 1, the signal and connector pin 120 is electrically coupled with inner layer 110 through the contact pad 144. The stub, also known as a “dangling via”, of the plated through-hole 140 is indicated by the distance “d”. No signal transmission occurs in the part of the through-hole pin 140 indicated by the distance “d”.

In particular, the stub behaves like capacitor. The capacitive loading of the stub will lower the impedance of the transmission line between the two transmission line segments of two signal layers. That is, the portion of the transmission line used for transmitting signals within the through-hole 140 has an impedance that is mismatched from the impedance of the system. The problem is more noticeable as the thickness of the PCB 100 increases, and the width of the through-hole 140 increases. As a result, the mismatching of impedance will degrade the performance or capability to transmit very high frequency signals through this transmission line coupled to inner layer 110.

One conventional solution to reducing the capacitance loading of the stub is a back drilling technique implemented during post procession of the PCB 100. However, several issues are presented that make back drilling unfeasible for reducing stub capacitance. For instance, the back drilling or counter bore removes the stub by controlled depth drilling from the back side 155 of the PCB 100 in a secondary, post processing PCB manufacturing process. However, this back drilling is not precise and may still leave a smaller stub. Also, the drilling could damage the integrity of the barrel of the through-hole 140. In addition, post processing, back drilling increases the manufacturing cost of the PCB 100 by approximately 25 percent due to extra manufacturing steps and lower yields.

Another conventional solution involves PCB construction using blind vias. However, blind vias are very expensive to construct since the PCB fabrication process is repeated multiple times depending on how many different levels of blind vias are created when connecting to internal layers of the PCB. That is, an additional step is included for creating blind vias of the same length. As a result, the cost of the PCB 100 could more than double, which is unacceptably high.

Therefore, a need exists to reduce the capacitive loading of stubs, or dangling vias, when designing and manufacturing PCBs.

### DISCLOSURE OF THE INVENTION

An apparatus and method for a printed circuit board for reducing capacitance loading of through-holes. The PCB includes a first electrically conductive via for connecting to the PCB a pin from a connector through a top layer of the PCB. The PCB comprises multiple layers that are electrically isolated from the first electrically conductive via. In addition, the connector provides an electrical signal through the pin that is electrically conductive. The PCB includes a second electrically conductive via that is proximate to the first electrically conductive via. The second electrically conductive via is electrically coupled to one of the multiple layers of the PCB. A trace electrically couples the first electrically conductive via to the second electrically conductive via on a bottom layer of the PCB. The trace allows the pin to be electrically coupled to one of the multiple layers of the PCB.

### BRIEF DESCRIPTION OF THE DRAWINGS

The above and other objects and advantages of the present invention will be more readily appreciated from the following detailed description when read in conjunction with the accompanying drawings, wherein:

PRIOR ART FIG. 1 is a cross-sectional view of a PCB illustrating the capacitive loading of a stub or dangling via.

FIG. 2 is a cross-sectional view of a PCB illustrating a double-barrel via structure for reducing capacitive loading of a through-hole when coupled with a signal and connector pin, in accordance with one embodiment of the present invention.

FIG. 3 is a cross-sectional view of a PCB illustrating a double-barrel via structure for reducing capacitive loading of a through-hole when coupled with a signal pin, in accordance with one embodiment of the present invention.

FIG. 4 is an isometric view of a PCB illustrating a double-barrel via structure for reducing capacitive loading of a through-hole, in accordance with one embodiment of the present invention.

FIG. 5 is a flow chart illustrating steps in a method for reducing capacitive loading of a through-hole in a PCB, in accordance with one embodiment of the present invention.

### BEST MODES FOR CARRYING OUT THE INVENTION

Reference will now be made in detail to embodiments of the present invention, an apparatus and method for reducing capacitive loading of through-holes in a PCB, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims.

Furthermore, in the following detailed description of the present invention, numerous specific details are set forth in order to provide a thorough understanding of the present invention. However, it will be recognized by one of ordinary skill in the art that the present invention may be practiced without these specific details. In other instances, well known methods, procedures, components, and circuits have not been described in detail as not to unnecessarily obscure aspects of the present invention.

Accordingly, embodiments of the present invention provide an apparatus and method for reducing capacitive loading in a PCB. As a result, other embodiments of the present invention serve the above purpose and improves the high frequency performance of a through-hole mounted daughter card to a backplane connector pair in a backplane interconnect system. In addition, other embodiments serve the above purpose and provides for the construction of the complimentary via in the double-barrel via structure of the present invention during normal PCB fabrication. That is, there is no additional cost when fabricating the PCB compared to conventional via stub capacitance reduction methods because there is no post or secondary fabrication process required.

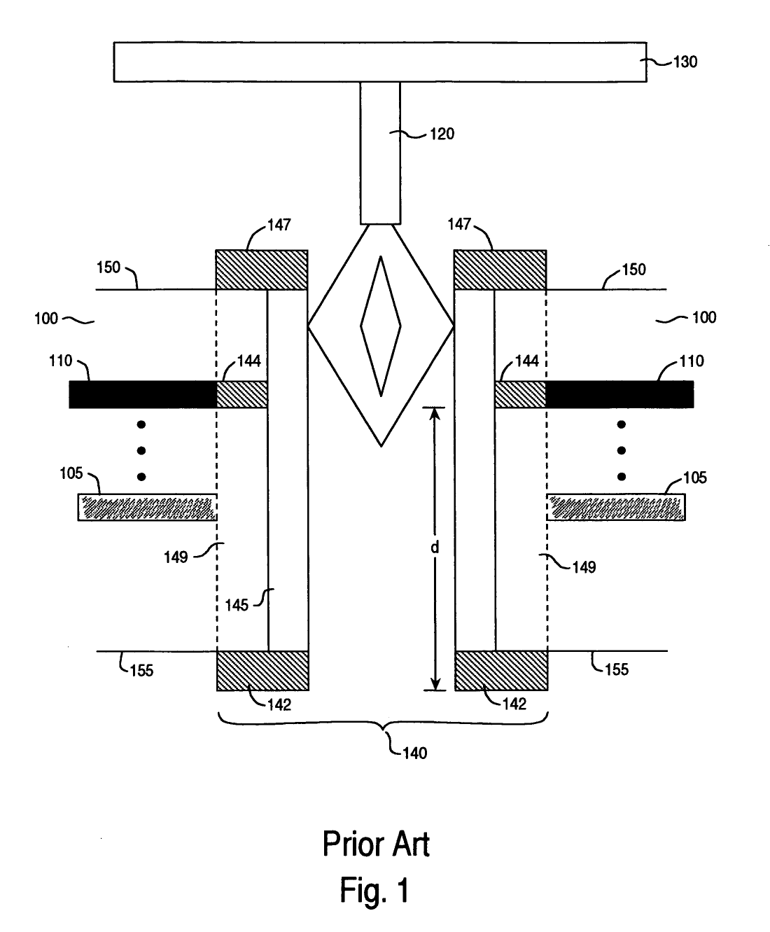

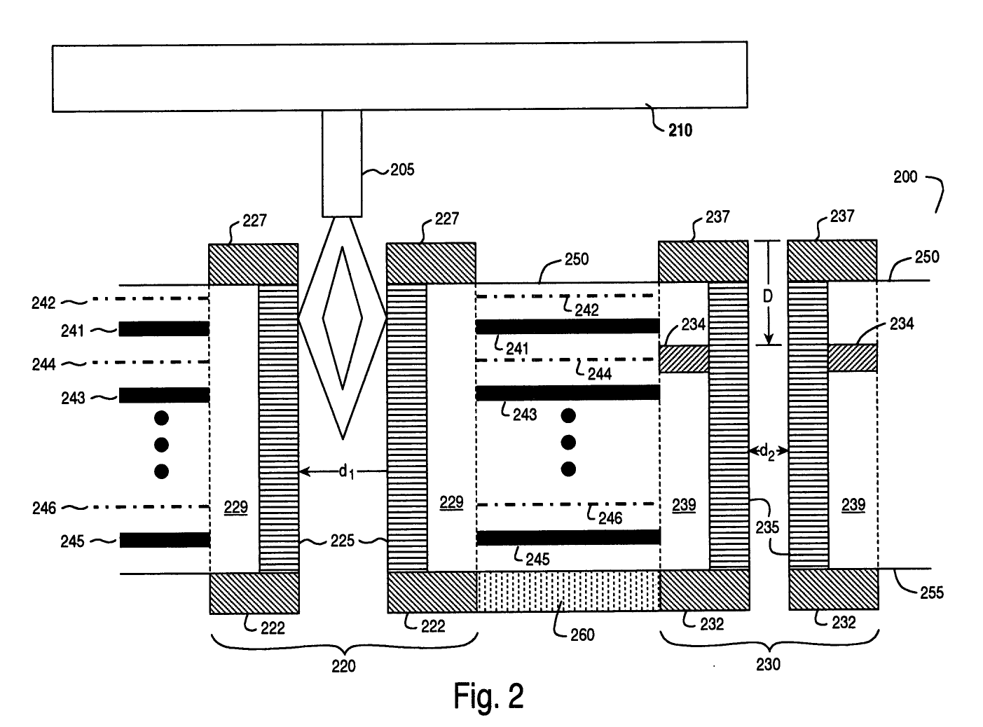

FIG. 2 is a cross-sectional view of a PCB 200 illustrating a double-barrel via structure for reducing capacitive loading of a through-hole when coupled with a connector pin that also provides electrical conductivity for signal transmission, in accordance with one embodiment of the present invention. The present embodiment is capable of providing high frequency signal transmission through the reduction of capacitive loading associated with through-holes. Also, the double barrel via structure of the present embodiment is produced without any additional fabrication steps, thereby keeping the fabrication costs constant while improving the frequency characteristics of the PCB.

The PCB 200 includes, in part, multiple inner layers of power planes, ground planes, and signal layers. As shown, PCB 200 is represented by ground or power planes, hereinafter referred to as “ground/power planes,” 241, 243, and 245. In addition, the PCB 200 also includes inner signal layers 242, 244, and 246. As shown, the PCB 200 can include any number of ground/power planes and any number of signal layers that combined make up the multi-layer PCB 200.

In addition, the double barrel via structure 200 includes a standard via 220. The standard via 220 is a first electrically conductive via for connecting a connector pin 205 from a connector through a top layer 250. The multiple inner layers of the PCB are electrically isolated from the standard via 220. The standard via 220 includes a contact pad 227 on the top surface 250, and a contact pad 222 on a bottom surface 255 of the PCB 200. The standard via 220 also includes a conductive hole plating 225 for signal transmission. The conductive hole plating 225 creates a barrel of the standard via 220. An insulating region 229 separates the conductive areas of the standard via 220 from the inner layers of the PCB 200. As shown in FIG. 2, the standard via 220 is entirely isolated electrically from the inner layers of the PCB 200.

As shown in FIG. 2, a pin 205 is inserted into the barrel of the standard via 220 so as to make contact with the conductive hole plating 225. The pin 205 is coupled to a connector 210. Typically, the connector 210 includes multiple pins that are inserted into corresponding vias for attaching and connecting to the PCB 100. That is, the connector 210 comprises a plurality of connector pins that are used for connecting to a plurality of vias in the PCB 200. For instance, the connector 210 could be associated with a daughter card (not shown) that is attached to the backplane represented by the PCB 200. In one embodiment, the pin is a pressed fit connector. Other embodiments support the use of other types of connector pins.

In addition, the pin 205 provides a signal path from the connector 210 to the PCB 200. That is, as shown in FIG. 2, a signal coming from connector 210 is transmitted through the electrically conductive pin 205 to the conductive hole plating 225 of the standard via 220. Since the standard via 220 is electrically isolated from the PCB, the signal is transmitted down to the electrically conductive contact pad 222. Since there is full transmission along the barrel of the standard via 220, there is no capacitive loading effects presented. That is, no stub is created in the standard via 220 in which the signal current does not traverse.

The double barrel via structure of the PCB 200 also includes a second electrically conductive via 230. That is, a complimentary signal via 230 is formed next to the standard via 220 to form the double barrel via structure. The complimentary signal via 230 is located proximate to the standard via 220. A trace 260 located on the bottom surface 255 electrically couples the standard via 220 to the complimentary via 230 for signal transmission. That is, a signal from the connector 210 is transmitted, in part through the pin 205, through the standard via 220, through the trace 260, and then through the complimentary via 230.

In one embodiment, formation of the complimentary signal via 230 is similar to the formation of the standard, connector via 220. That is, the complimentary signal via 230 can be formed at the same time, and using the same fabrication steps, as when forming the standard via 220, as well as the other vias in the PCB 200.

The complimentary signal via 230 is used for transmitting the signal to the inner layers of the PCB 200. That is, the complimentary signal via 230 is electrically coupled to one of the inner layers (e.g., power/ground plane, signal layer, etc.) of the PCB 200. The complimentary via 230 includes a contact pad 237 on the top surface 250 of the PCB 200, and a contact pad 232 on a bottom surface 255 of the PCB 200. The complimentary via 230 also includes a conductive hole plating 235 for signal transmission. The conductive hole plating 235 creates a barrel of the complimentary via 230. An insulating region 239 separates the conductive areas of the complimentary via 230 from the inner layers of the PCB 200.

Also, the complimentary via 230 is electrically coupled to the standard via 220. That is, the contact pad 232 is electrically coupled to the trace 260 which is electrically coupled to the standard via 220. As such, the signal from the connector 210 is transmitted to the complimentary via 230.

In addition, the complimentary via 230 includes a contact pad 234. As such, the complimentary via 230 is electrically coupled to the inner signal layer 244 of the PCB 200 through the contact pad 234. As such, in one embodiment, the signal from the connector 210 is transmitted to the inner signal layer 244 of the PCB 200.

Depending on the location and formation of the contact pad 234, the complimentary via 230 can be electrically coupled to any of the inner layers of the PCB 200. As such, the pin 205 is able to be electrically coupled to any one of the multiple, inner layers of the PCB 200. For instance, the double barrel via structure of FIG. 2 could be electrically coupled to power/ground plane 243, or signal layer 246, etc.

When electrically coupling the secondary via 230 to the inner signal layer 244 of the multi-layer PCB 200, a stub is created in the complimentary via 230, in which the signal does not traverse. For instance, in FIG. 2, the stub, or dangling via, of the complimentary via 230 is indicated by the distance “D”. The stub is formed between one of the inner layers of the PCB 200 and the top layer 250, approximately. In FIG. 2, the stub if formed between the signal layer 244 and the top layer 250 approximately. No signal transmission occurs in the part of the complimentary via 230 indicated by the distance “D”.

A corresponding capacitive loading is associated with the stub. That is, the stub indicated by the distance “D” is associated with a capacitance that is less than a capacitance that would have been formed between the inner signal layer 244 and the bottom layer 255, approximately, had the standard conductive via 220 been electrically coupled to the inner layer 244.

The double barrel via structure of FIG. 2 in embodiments of the present invention is able to reduce the stub capacitance when compared to the conventional technique of connecting one via to the inner layers of the PCB. In particular, the stub length is reduced when the signal is coupled to inner layers nearer the top surface 250 of the PCB 200. That is, when coupling to a signal layer that is located in the top half of the PCB 200, the stub length indicated by distance “D” would be shorter than an corresponding stub length measured from the inner layer 244 to approximately the bottom surface 255 of the PCB 200, as would occur in conventional systems.

In other words, the stub of the standard, connector via is eliminated when the signal is coupled to the complimentary, signal via through the bottom layer indicated by the contact pad 222, pad 232, and the trace 260. As such, the capacitance is reduced because the capacitance is proportional to the stub length. In this case, the stub length, “D”, would be shorter, when coupling to an inner layer in the top half of the PCB 200.

In addition, as shown in FIG. 2, the diameter of the barrel of the standard via 220 is larger than the diameter of the complimentary via 230. In particular, the diameter of the standard via 220 is indicated by the distance, “d₁”. The diameter of the complimentary via 230 is indicated by the distance, “d₂”. In the double barrel via structure of FIG. 2, d₁ is larger than d₂.

In particular, the double barrel via structure of FIG. 2 exhibits a smaller parasitic capacitance when compared to the conventional standard via coupling to the inner layers of the PCB. The capacitance is reduced because the capacitance is proportional to the diameter of the stub and corresponding via. Specifically, the capacitance associated with the stub indicated by distance, D, is associated with a diameter, d₂, of the barrel. The diameter, d₂, is smaller than the diameter, d₁, of the barrel associated with a potential stub associated with the standard via 220. As such, by using a smaller diameter, d₂, the capacitance of the double barrel via structure is smaller when compared to conventional techniques using a single barrel via structure.

As such, the double barrel via structure is able to reduce the stub capacitance of connector vias by reducing the stub length, and reducing the diameter of the stub. Selection of the connector via for formation of the double barrel via structure is thus dependent on both of these factors. In one embodiment, when the resulting stub capacitance of the double barrel via structure is less than the stub capacitance when using the conventional single via structure, the corresponding connector via is a potential candidate for the formation of a double barrel via structure. In other embodiments, when the resulting stub capacitance of the double barrel via structure is less than, over a corresponding threshold, the stub capacitance when using the conventional single via structure, the corresponding connector via is a potential candidate for the formation of a double barrel via structure. That is, the reduction of the capacitance of the resulting stub capacitance from the double barrel via structure exceeds a threshold.

In still other embodiment, the diameters of each via in the double barrel via structure is approximately the same size. That is, the diameter of the standard, connector via 220 is approximately the same size as the diameter of the signal, complimentary via 230. a reduction in the capacitance is still realized since the stub capacitance of the complimentary vias 230 is shorter than the stub capacitance of the standard via, if coupled to the inner layers of the PCB 200.

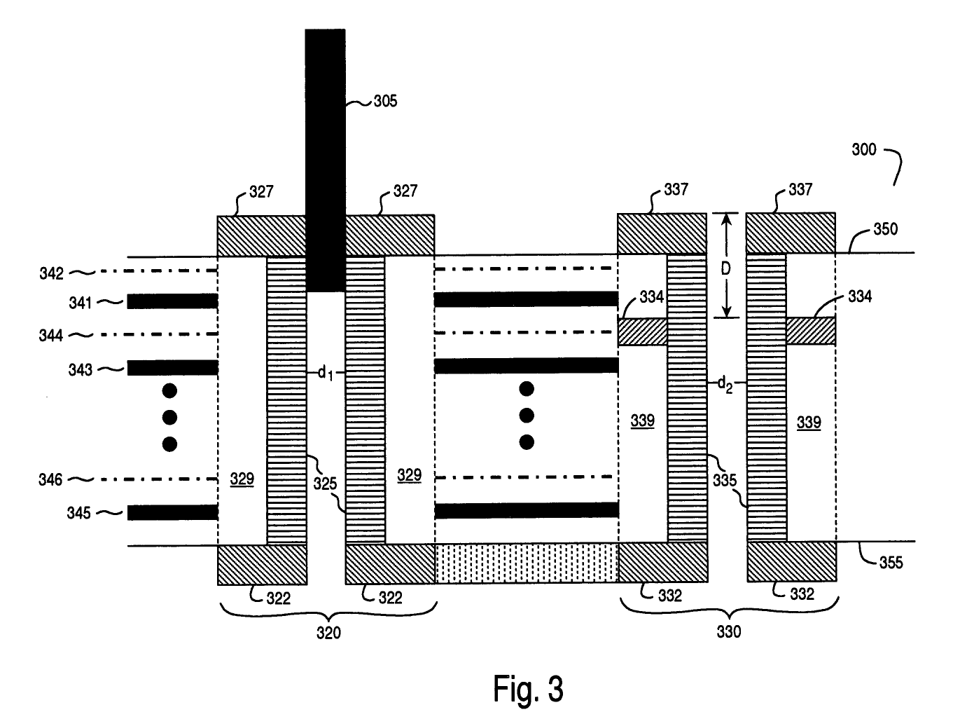

FIG. 3 is a cross-sectional view of a PCB 300 illustrating a double-barrel via structure for reducing capacitive loading of a through-hole when coupled with a signal trace, or pin, that provides electrical conductivity for signal transmission, in accordance with one embodiment of the present invention. The present embodiment is capable of providing high frequency signal transmission through the reduction of capacitive loading associated with through-holes. Also, the double barrel via structure of the present embodiment is produced without any additional fabrication steps, thereby keeping the fabrication costs constant while improving the frequency characteristics of the PCB.

The double barrel via structure of FIG. 3 is similar to the double barrel via structure of FIG. 2. However, the vias in the double barrel via structure of FIG. 3 are used for signal transmission primarily, and not for connecting, such as when connecting a daughter card to the back plane represented by the PCB 300.

The PCB 300 includes, in part, multiple inner layers of power planes, ground planes, and signal layers. As shown, PCB 300 is represented by one or more ground or power planes, hereinafter referred to as “ground/power planes,” 341, 343, and 345. In addition, the PCB 300 also includes one or more inner signal layers 342, 344, and 346.

In addition, the double barrel via structure 300 includes a first electrically conductive via 320. The first electrically conductive via receives an electrical signal from a signal trace, or pin, 305 through a top layer 350 of the PCB 300. That is, the signal trace 305 is coupled to and makes contact with the conductive hole plating 325 for signal transmission through the via 320. In addition, the multiple inner layers of the PCB 300 are electrically isolated from the first electrically conductive via 320. The via 320 includes a contact pad 327 on the top surface 350, and a contact pad 322 on a bottom surface 355 of the PCB 300. The via 320 also includes a conductive hole plating 325 for signal transmission. The conductive hole plating 325 creates a barrel of the via 320. An insulating region 329 separates the conductive areas of the via 320 from the inner layers of the PCB 300.

In addition, the signal trace 305 provides a signal path to the PCB 300. That is, as shown in FIG. 3, a signal is transmitted through the electrically conductive pin 305 to the conductive hole plating 325 of the first via 320. Since the via 320 is electrically isolated from the PCB 300, the signal is transmitted down to the electrically conductive contact pad 322. Since there is full transmission along the barrel of the via 320, there is no capacitive loading effects presented. That is, no stub is created in the via 320 in which the signal current does not traverse.

The double barrel via structure of the PCB 300 also includes a second electrically conductive via 330. That is, the second 330 is formed next to the via 320 to form the double barrel via structure. The via 330 is located proximate to the via 320. The secondary via 330 is used for transmitting the signal to the inner layers of the PCB 300. That is, the secondary signal via 330 is electrically coupled to one of the inner layers (e.g., power/ground plane, signal layer, etc.) of the PCB 300. The secondary via 330 includes a contact pad 337, and a contact pad 332 on a bottom surface 355. The secondary via 330 also includes a conductive hole plating 335 for signal transmission. The conductive hole plating 335 creates a barrel of the secondary via 330. An insulating region 339 separates the conductive areas of the secondary via 330 from the inner layers of the PCB 300.

A trace 360 located on the bottom surface 355 electrically couples the first via 320 to the second via 330 for signal transmission. That is, a signal from the trace 305 is transmitted through the via 320, through the trace 360, and then through the second via 330.

In addition, the second via 330 includes a contact pad 334. As such, the second via 330 is electrically coupled to the inner signal layer 344 of the PCB 300 through the contact pad 334. As such, in one embodiment, the signal is transmitted from the signal trace 305 to the inner signal layer 344 of the PCB 300. Also, the contact pad 334 can be placed to couple to any of the multiple, inner layers of the PCB 300. for instance, the double barrel via structure of FIG. 3 could be electrically coupled to power/ground plane 343, or signal layer 346, etc.

When electrically coupling the second via 330 to the inner signal layer 344 of the multi-layer PCB 300, a stub is created in which the signal does not traverse. For instance, in FIG. 3, the stub of the second via 330 is indicated by the distance “D”. The stub is formed between one of the inner layers of the PCB 300 and the top layer 350, approximately. In FIG. 3, the stub if formed between t signal layer 344 and the top layer 350 approximately. No signal transmission occurs in the part of the second via 330 indicated by the distance “D”.

In particular, the double barrel via structure of FIG. 3 in embodiments of the present invention is able to reduce the stub capacitance when compared to the conventional techniques. In particular, the stub length is reduced when the signal is coupled to inner layers nearer the top surface 350 of the PCB 300. That is, when coupling to a signal layer that is located in the top half of the PCB 300, the stub length indicated by distance “D” would be shorter than an corresponding stub length measured from the inner layer 344 to approximately the bottom surface 355 of the PCB 300, as would occur in conventional systems. In this case, the potential, longer, stub of the first via 320 is eliminated when the signal is coupled to the second via 330.

In the present embodiment, the diameter, d₁, of the first via 320 is substantially similar in size to the diameter, d₂, of the second via. As such, the reduction of capacitance of the double barrel via structure of FIG. 3 is primarily from the reduction of length of the stub. However, in other embodiments of the present invention, the diameter, d₁, is larger than a diameter, d₂, of the second via in FIG. 3, as when using a first via that is also a connector via for accepting a connector pin. As such, by using a smaller diameter, d₂, than d₁ the capacitance of the double barrel via structure is smaller when compared to conventional techniques using a single barrel via structure. As such, the double barrel via structure of FIG. 3 is able to reduce the stub capacitance of connector vias by reducing the stub length, and possibly reducing the diameter of the stub.

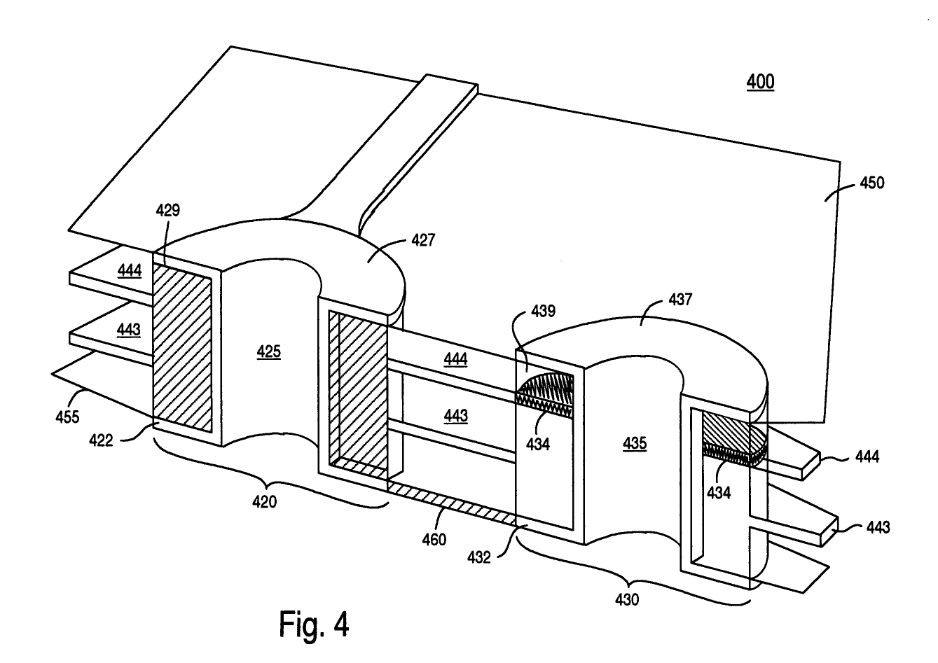

FIG. 4 is an isometric view of an exemplary PCB 400 illustrating a double-barrel via structure for reducing capacitive loading of a through-hole, when coupled with a pin that provides signal transmission, in one embodiment, and additional connecting features in another embodiment. The present embodiment is capable of providing high frequency signal transmission through the reduction of capacitive loading associated with through-holes.

The double barrel via structure of FIG. 4 is similar to the double barrel structures of FIGS. 2 and 3. That is the double barrel via structure of FIG. 4 is representative of via structures of both FIGS. 2 and 3 and can be used for signal transmission and connecting daughter cards to backplanes, or just signal transmission. As shown in FIG. 4, the PCB 400 is represented by one or more inner layers that are ground/power planes or signal layers. For instance, the PCB 400 is represented by inner layers 443 and 444.

In addition, the double barrel via structure 300 includes a first electrically conductive via 420. The first electrically conductive via receives an electrical signal from a pin (not shown), in one embodiment. In another embodiment, the first electrically conductive via receives an electrical signal through the top layer 450 of the PCB 400. A signal trace 426 provides the signal to the top layer 450, and to the first electrically conductive via 420. The multiple inner layers of the PCB 400 are electrically isolated from the first via 420. The via 420 includes a contact pad 427 on the top surface 450, and a contact pad 422 on a bottom surface 455 of the PCB 400. The via 420 also includes a conductive hole plating 425 for signal transmission that creates a barrel. An insulating region 429 separates the conductive areas of the via 420 from the inner layers of the PCB 400.

The double barrel via structure of the PCB 400 also includes a second electrically conductive via 430. That is, the second 430 is formed and located proximate to the via 420. The second via 430 is used for transmitting the signal to the inner layers of the PCB 400. That is, the second via 430 is electrically coupled to one of the inner layers (e.g., power/ground plane, signal layer, etc.) of the PCB 400. The second 430 includes a contact pad 437, and a contact pad 432 on a bottom surface 455. The second via 430 also includes a conductive hole plating 435 for signal transmission. An insulating region 439 separates the conductive areas of the second via 430 from the inner layers of the PCB 400. A trace 460 located on the bottom surface 455 electrically couples the first via 420 to the second via 430 for signal transmission.

In addition, the second via 430 includes a contact pad 434. As such, the second via 430 is electrically coupled to the inner signal layer 444 of the PCB 400 through the contact pad 434. Also, the contact pad 434 can be placed to couple to any of the multiple, inner layers of the PCB 400.

In particular, the double barrel via structure of FIG. 4 in embodiments of the present invention is able to reduce the stub capacitance when compared to the conventional techniques, as described previously. Specifically, the double barrel via structure of FIG. 4 is able to reduce the stub capacitance of connector vias by reducing the stub length, and reducing the diameter of the stub, each taken alone or in combination. Selection of the connector via for formation of the double barrel via structure is thus dependent on one or both of these factors.

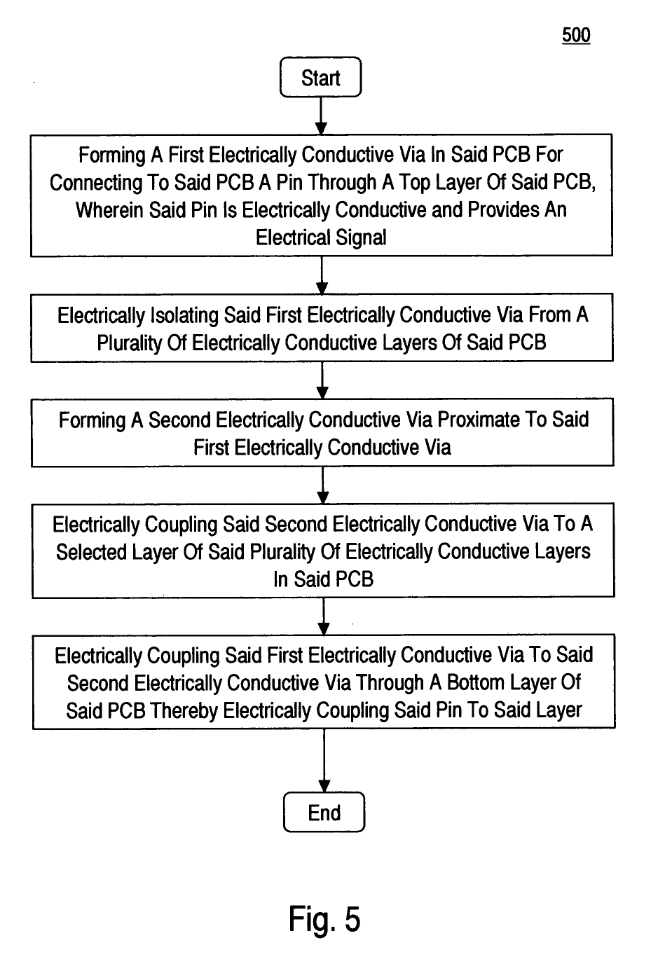

Now referring to FIG. 5, a flow chart 500 is described illustrating steps in a method for reducing capacitive loading in through-holes of a PCB, in accordance with one embodiment of the present invention. This promotes higher frequency performance of through-hole mounted daughter cards to backplane connector pairs in a backplane interconnect system.

At 510, the present embodiment begins by forming a first electrically conductive via in the PCB. In one embodiment, the first via provides signal conduction through the PCB. In another embodiment, the first via provides signal conduction of a signal through the PCB and also provides for connecting to the PCB a connector, such as through connecting a pressed fit connector pin through a top layer of the PCB. As such, the pin is electrically conductive and provides an electrical signal.

At 520, the present embodiment electrically isolates the first electrically conductive via from a plurality of electrically conductive layers in the PCB. That is, a stub capacitance that would have been associated with the first via, had the first via been coupled to the inner layer of the PCB, is eliminated. As a result, the signal passes through the first via without any capacitive loading associated with the first via.

At 530, the present embodiment forms a second electrically conductive via proximate to the first electrically conductive via. The second via is used for transmitting the signal to the inner layers of the PCB. In one embodiment, a diameter of the first via is larger than the diameter of the second via. In another embodiment, a diameter of the first via is substantially similar to the diameter of the second via.

In addition, the second via is formed when a stub formed between the top layer of the PCB and the selected inner layer exhibits a capacitance that is less than a capacitance that would have been formed between the selected layer and the bottom layer. In another embodiment, the second via is formed when a reduction of capacitance that exceeds a threshold is realized between the capacitance loading of the double barrel via structure and the conventional single via structure.

At 540, the present embodiment electrically couples the second via to a selected layer of the plurality of inner, electrically conductive layers of the PCB. That is, the second via is electrically coupled to one of the inner layers of the PCB.

At 550, the present embodiment electrically couples the first via to the second via through a bottom layer of the PCB. As such, the signal transmitted through a pin inserted in the first via is electrically coupled to the inner layer of the PCB through the second via.

While the method of the embodiment illustrated in flow chart 500 shows specific sequences and quantity of steps, the present invention is suitable to alternative embodiments. For example, not all the steps provided for in the methods are required for the present invention. Furthermore, additional steps can be added to the steps presented in the present embodiment. Likewise, the sequences of steps can be modified depending upon the application.

Accordingly, by constructing a double-barrel via structure the capacitive loading of through-holes in a PCB are reduced, in embodiments of the present invention. Other embodiments of the present invention serve the above purpose and improves the high frequency performance of a through-hole mounted daughter card to a backplane connector pair in a backplane interconnect system. In addition, other embodiments serve the above purpose and provides for the construction of the complimentary via in the double-barrel via structure of the present invention during normal PCB fabrication. That is, there is no additional cost when fabricating the PCB compared to conventional via stub capacitance reduction methods because there is no post or secondary fabrication process required.

An apparatus and method for reducing capacitive loading of through-holes in a PCB is thus described. While the invention has been illustrated and described by means of specific embodiments, it is to be understood that numerous changes and modifications may be made therein without departing from the spirit and scope of the invention as defined in the appended claims and equivalents thereof. Furthermore, while the present invention has been described in particular embodiments, it should be appreciated that the present invention should not be construed as limited by such embodiments, but rather construed according to the below claims.

What is claimed is:

1. A printed circuit board (PCB) for reducing capacitance loading of through-hole pins comprising:
a first electrically conductive via for connecting to said PCB a pin from a connector through a top layer of said PCB, wherein said PCB comprises multiple layers that are electrically isolated from said first electrically conductive via, and wherein said connector provides an electrical signal through said pin that is electrically conductive;
a second electrically conductive via proximate to said first electrically conductive via, wherein said second electrically conductive via is electrically coupled to one of said multiple layers of said PCB;
a trace electrically coupling said first electrically conductive via to said second electrically conductive via on a bottom layer of said PCB to allow said pin to be electrically coupled to said one of said multiple layers of said PCB.

2. The PCB of claim 1, wherein said connector comprises a pressed fit connector.

3. The PCB of claim 1, wherein said second electrically conductive via is electrically coupled to a signal layer of said PCB.

4. The PCB of claim 1, wherein said second electrically conductive via is electrically coupled to a power/ground plane of said PCB.

5. The PCB of claim 1, wherein a first diameter of said first electrically conductive via is larger than a second diameter of said second electrically conductive via.

6. The PCB of claim 1, wherein said multiple layers comprises:
at least one ground/power planes; and
a plurality of signal layers.

7. The PCB of claim 1, wherein said second electrically conductive via comprises a stub formed between said one of said multiple layers of said PCB and said top layer, wherein said stub exhibits a capacitance that is less than a capacitance that would have been formed between said one of said multiple layers of said PCB and said bottom layer had said first electrically conductive via been electrically coupled to said one of said multiple layers.

8. The PCB of claim 1, wherein said connector further comprises:
a plurality of pins for connecting to a plurality of vias in said PCB.

9. A printed circuit board (PCB) for reducing capacitance loading of through-hole pins, comprising:
a first electrically conductive via for receiving an electrical signal from a signal pin through a top layer of said PCB, wherein said PCB comprises multiple layers that are electrically isolated from said first via;
a second electrically conductive via proximate to said first electrically conductive via, wherein said second electrically conductive via is electrically coupled to one of said multiple layers of said PCB;
a trace electrically coupling said first electrically conductive via to said second electrically conductive via on a bottom layer of said PCB to electrically couple said signal pin to said one of said multiple layers of said PCB.

10. The PCB of claim 9, wherein said second electrically conductive via is electrically coupled to a signal layer of said PCB.

11. The PCB of claim 9, wherein said second electrically conductive via is electrically coupled to a power/ground plane of said PCB.

12. The PCB of claim 9, wherein a first diameter of said first electrically conductive via is substantially similar to a second diameter of said second electrically conductive via.

13. The PCB of claim 9, wherein a first diameter of said first electrically conductive via is larger than a second diameter of said second electrically conductive via.

14. The PCB of claim 9, wherein said multiple layers comprises:
at least one ground/power planes; and
a plurality of signal layers.

15. The PCB of claim 9, wherein said second electrically conductive via comprises a stub formed between said one of said multiple layers of said PCB and said top layer, wherein said stub exhibits a capacitance that is less than a capacitance that would have been formed between said one of said multiple layers of said PCB and said bottom layer had said first electrically conductive via been electrically coupled to said one of said multiple layers.

16. The PCB of claim 9, wherein said signal pin is coupled to a connector, wherein said signal pin is used for connecting said connector to said PCB.

17. A method for reducing capacitance loading of through-hole pin in a printed circuit board (PCB), comprising:
forming a first electrically conductive via in said PCB for connecting to said PCB a pin through a top layer of said PCB, wherein said pin is electrically conductive and provides an electrical signal;
electrically isolating said first electrically conductive via from a plurality of electrically conductive layers of said PCB;
forming a second electrically conductive via proximate to said first electrically conductive via;
electrically coupling said second electrically conductive via to a selected layer of said plurality of electrically conductive layers in said PCB; and
electrically coupling said first electrically conductive via to said second electrically conductive via through a bottom layer of said PCB thereby electrically coupling said pin to said layer.

18. The method of claim 17, further comprising:
forming said first electrically conductive via to receive said pin that comprises a pressed fit connector, wherein said pin connects a connector comprising said pressed fit connector to said PCB.

19. The method of claim 17, further comprising:
forming said second electrically conductive via such that a first diameter of said first electrically conductive via is larger than a second diameter of said second electrically conductive via.

20. The method of claim 17, further comprising:
forming said second electrically conductive via when a stub formed between said selected layer and said top layer exhibits a capacitance that is less than a capacitance that would have been formed between said selected layer and said bottom layer had said first electrically conductive via been electrically coupled to said selected layer.
